(19) United States
(12) Patent Application Publication
(10) Pub. No.: US 2026/0282684 A1
(43) Pub. Date: Sep. 17, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: JUN-HO HWANG, Yongin-si (KR); HYUNGJUN AN, Yongin-si (KR); JIPHYO HONG, Yongin-si (KR)

(21) Appl. No.: 19/558,697

(22) Filed: Mar. 6, 2026

(30) Foreign Application Priority Data
Mar. 17, 2025 (KR) 10-2025-0034040

(51) Int. Cl. H10K 59/131; H10K 59/12; H10K 59/88

(52) U.S. Cl. CPC H10K 59/131; H10K 59/1201; H10K 59/88

(57) ABSTRACT

A display device includes: a substrate including a display area and a non-display area positioned outside the display area; a thin film transistor positioned on the substrate; and a light-emitting element positioned in the display area of the substrate and electrically connected to the thin film transistor. The non-display area includes a pad area in which signal pads and dummy pads are arranged along a first direction, the signal pads are connected to signal wirings, respectively, and at least one of the dummy pads is positioned between two adjacent signal pads of the signal pads and is electrically connected to one of the two adjacent signal pads.

### CROSS-REFERENCE TO RELATED APPLICATION

This application claims priority to Korean Patent Application No. 10-2025-0034040, filed on, Mar. 17, 2025, and all the benefits accruing therefrom under 35 U.S.C. §119, the content of which in its entirety is herein incorporated by reference.

### BACKGROUND

Embodiments relate to a display device, a method of manufacturing the display device, and an electronic device including the display device.

A display panel includes a display area configured to display an image and a non-display area positioned outside the display area. As an area occupied by the display area among the display panel expands, various functions configured to be integrated with or connected to the display panel are being added. As a method to add various functions while expanding the area, research is being conducted on a display device configured to have various components arranged in the display area.

As the resolution of a display device increases, pad sizes become smaller and pitches decrease, such that it may be desired to improve reliability of the display device and electronic device by preventing corrosion of the pads.

### SUMMARY

Embodiments of the present disclosure may provide a display device with improved reliability, a method of manufacturing the display device, and an electronic device including the display device.

However, these problems are examples, and the scope of embodiments of the present disclosure are not limited thereto.

An embodiment of the present disclosure discloses a display device including: a substrate including a display area and a non-display area positioned outside the display area; a thin film transistor positioned on the substrate; and a light-emitting element positioned in the display area of the substrate and electrically connected to the thin film transistor, wherein the non-display area includes a pad area in which signal pads and dummy pads are arranged along a first direction, the signal pads are connected to signal wirings, respectively, and at least one of the dummy pads is positioned between two adjacent signal pads of the signal pads and is electrically connected to one of the two adjacent signal pads.

In some embodiments, the signal pads may include a first signal pad electrically connected to a first dummy pad which is relatively nearest to the first signal pad from among the dummy pads.

In some embodiments, the first signal pad may be connected to the first signal wiring, and the first dummy pad may be connected to the first signal wiring.

In some embodiments, the signal pads may include a second signal pad electrically connected to second dummy pads which are respectively adjacent to opposite sides of the second signal pad.

In some embodiments, an electric field difference between the first signal pad and another signal pad adjacent to the first signal pad may be smaller than an electric field difference between the second signal pad and another signal pad adjacent to the second signal pad.

In some embodiments, two or more dummy pads may be sequentially arranged on at least one side of the opposite sides of the second signal pad.

In some embodiments, the second signal pad may be connected to the second signal wiring, and the second dummy pad may be connected to the second signal wiring.

In some embodiments, at least two among the signal pads and the dummy pads may be arranged such that the at least two are inclined rather than parallel to each other.

In some embodiments, an upper end of the signal pads and the dummy pads in a second direction perpendicular to the first direction may be positioned on a same line in the first direction.

In some embodiments, the display device further includes: a connection circuit substrate having a surface on which a plurality of connection pads are arranged along the first direction, wherein the connection circuit substrate is positioned such that the connection circuit substrate corresponds to the pad area, and each of the plurality of connection pads may have at least one area which overlaps with the corresponding signal pads and is electrically connected thereto.

Another embodiment of the present disclosure discloses a method of manufacturing a display device including: preparing a substrate including a display area and a non-display area positioned outside the display area; and manufacturing panel pads along a first direction in a pad area of the non-display area, wherein the manufacturing the panel pads includes: arranging first pad electrodes on the substrate; arranging a second pad electrode on each of the first pad electrodes; arranging an insulating material between the second pad electrodes; and removing the insulating material.

In some embodiments, the arranging the insulating material between the second pad electrodes may include: arranging an organic insulating material between the second pad electrodes; and arranging an inorganic insulating material on the second pad electrodes and the organic insulating material.

In some embodiments, the removing the insulating material may include: removing the organic insulating material; and removing the inorganic insulating material.

In some embodiments, the panel pads include the signal pads and the dummy pads, and at least one of the dummy pads is positioned between two adjacent signal pads of the signal pads, and may be electrically connected to one of the two adjacent signal pads.

In some embodiments, the signal pads may include a first signal pad electrically connected to a first dummy pad which is relatively nearest to the first signal pad from among the dummy pads.

In some embodiments, the signal pads may include a second signal pad electrically connected to second dummy pads which are respectively adjacent to opposite sides of the second signal pad.

In some embodiments, an electric field difference between the first signal pad and another signal pad adjacent to the first signal pad may be smaller than an electric field difference between the second signal pad and another signal pad adjacent to the second signal pad.

In some embodiments, the first pad electrodes and the second pad electrodes each include to a first layer, a second layer, and a third layer which are sequentially stacked, and the first layer and the third layer each include titanium (Ti), and the second layer may include aluminum (Al).

A further embodiment of the present disclosure discloses an electronic device including: a display module; a processor; a memory; and a power module, wherein the display module includes: a substrate including a display area and a non-display area positioned outside the display area; a thin film transistor positioned on the substrate; and a light-emitting element positioned in the display area of the substrate and electrically connected to the thin film transistor, wherein the non-display area includes a pad area in which signal pads and dummy pads are arranged along a first direction, the signal pads are connected to signal wirings, respectively, and at least one of the dummy pads is positioned between two adjacent signal pads of the signal pads and is electrically connected to one of the two adjacent signal pads.

In some embodiments, the signal pads include a first signal pad electrically connected to a first dummy pad which is relatively nearest to the first signal pad from among the dummy pads, and a second signal pad electrically connected to second dummy pads which are respectively adjacent to opposite sides of the second signal pad, and an electric field difference between the first signal pad and another signal pad adjacent to the first signal pad may be smaller than an electric field difference between the second signal pad and another signal pad adjacent to the second signal pad.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a plan view schematically illustrating a display device according to an embodiment of the present disclosure;

FIG. 2 is a cross-sectional view schematically illustrating an example of a part of a cross-section taken along line I-I' of FIG. 1;

FIG. 3 is an enlarged view illustrating an example of area A in FIG. 1;

FIG. 4 is an enlarged view illustrating another example of area A in FIG. 1;

FIGS. 5 to 8 are cross-sectional views sequentially illustrating a method of manufacturing a display device according to an embodiment of the present disclosure;

FIG. 9 is a cross-sectional view schematically illustrating a cross-section taken along line II-II' of FIG. 1;

FIG. 10 is a cross-sectional view schematically illustrating a cross-section taken along line III-III' of FIG. 1;

FIG. 11 is a block diagram of an electronic device according to an embodiment of the present disclosure; and

FIG. 12 is a schematic diagram of an electronic device according to various embodiments.

### DETAILED DESCRIPTION

It is to be understood that the present disclosure is susceptible to various changes and may have numerous embodiments. Specific embodiments are illustrated in the drawings and described in the detailed description. The effects and features of the present disclosure, as well as a method of achieving them, will become apparent with reference to the embodiments described in detail below with the following drawings. However, the present disclosure is not limited to the embodiments disclosed herein and may be implemented in various forms.

In the following embodiments, terms such as "first," "second," and the like are used for the purpose of distinguishing one component from another and are not used to limit the components.

In the following embodiments, singular expressions are understood to include plural expressions unless the context clearly indicates otherwise.

In the following embodiments, terms such as "include," or "have," and the like are used to indicate the presence of the feature or the component described in the description, and do not exclude the possibility that one or more other features or components may be added.

In the following embodiments, when a portion of a unit, area, component, or the like is described as being "on" or "above" another portion, it includes not only the case where it is directly on or above another portion, but also the case where another unit, area, component, or the like is interposed therebetween.

In the following embodiments, terms such as "connect" or "combine" do not necessarily imply a direct and/or fixed connection or coupling of two elements, and do not exclude the interposition of another element between the two elements, unless the context clearly indicates otherwise.

In the drawings, the size of components may be exaggerated or reduced for convenience of description. For example, the size and/or thickness of each component illustrated in the drawings are arbitrarily illustrated for convenience of description, and therefore the present disclosure is not necessarily limited to what is illustrated.

Hereinafter, example embodiments of the present disclosure will be described in detail with reference to the following drawings. When describing with reference to the drawings, identical or corresponding components are denoted by the same drawing reference numerals, and any redundant description thereof will be omitted.

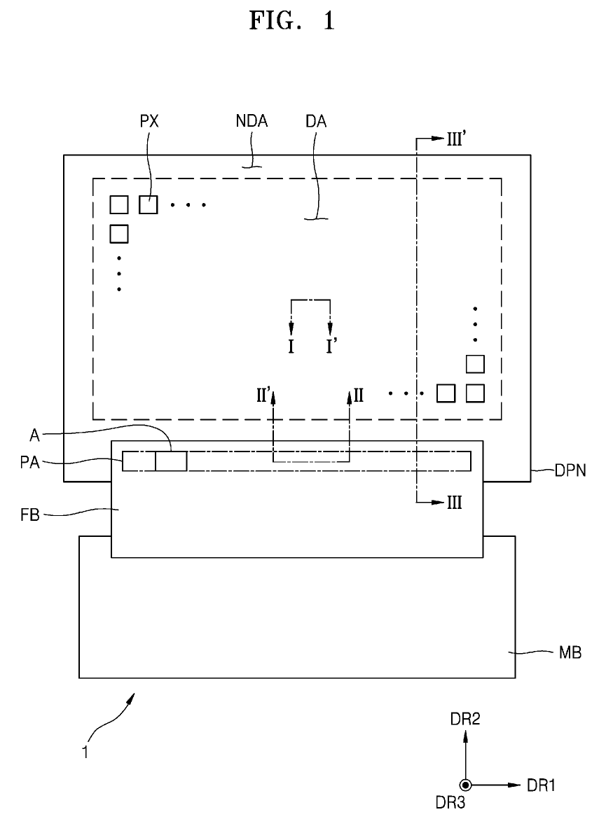

Referring to FIG. 1, a display device 1 may include a display panel (DPN). In some embodiments, as an optional embodiment, the display device 1 may additionally include a connection circuit substrate FB or a main circuit substrate MB. The display panel DPN, the connection circuit substrate FB and the main circuit substrate MB may be electrically connected.

The display panel DPN may include a display area DA and a non-display area NDA. The display area DA is a portion where an image is displayed, and the non-display area NDA surrounding the display area DA may be a portion where circuits and/or signal lines for generating and/or transmitting various signals applied to the display area DA are arranged.

More particularly, a substrate 100 of the display panel DPN may include the display area DA and the non-display area NDA positioned outside the display area DA. The substrate 100 may include a light-emitting element positioned in the display area DA and electrically connected to a thin film transistor TFT.

The non-display area NDA may include a pad area PA where a plurality of panel pads PP are arranged along a first direction DR1. The display panel DPN may be connected to the connection circuit substrate FB in the pad area PA.

The non-display area NDA may be adjacent to the display area DA. The non-display area NDA may be positioned on at least one side of the display area DA in the display panel DPN. As an example, the non-display area NDA may surround the display area DA. In FIG. 1, a boundary between the display area DA and the non-display area NDA is indicated by a dotted line. However, it is to be understood that this is an exemplary illustration, and the non-display area NDA, when adjacent to the display area DA, may have various patterns and is not limited to any one embodiment.

In some embodiments, the non-display area NDA, more particularly, the pad area PA positioned in the non-display area NDA, may be an area where one end of the connection circuit substrate FB is combined. A plurality of panel pads PP may be arranged on the pad area PA to be electrically connected to the connection circuit substrate FB. A panel pad PP may be a signal pad SP or a dummy pad DP. The display panel DPN may be electrically combined to external components such as the connection circuit substrate FB and the main circuit substrate MB through the pad area PA.

Although not illustrated in FIG. 1, a driving unit configured to generate and/or process various signals for driving the display panel DPN may be positioned in the non-display area NDA. The driving unit may include a data driving unit configured to apply a data signal to a data line, a gate driving unit configured to apply a gate signal to a scan line, and a signal control unit configured to control the data driving unit and the gate driving unit. Data signals, or the like may be applied to pixels PX at predetermined timings according to scan signals generated by the gate driving unit.

The connection circuit substrate FB is positioned in the pad area PA of the display panel DPN to connect the main circuit substrate MB to the display panel DPN. The connection circuit substrate FB may be positioned on one side of the display panel DPN extending along a second direction DR2.

The connection circuit substrate FB may be provided as a single component, and is not limited to any one embodiment. As another example, although not illustrated, a plurality of connection circuit substrates FB may be provided and spaced apart from each other along the first direction DR1 in the pad area PA.

The connection circuit substrate FB may include a plurality of connection pads FP arranged along the first direction on a surface of the connection circuit substrate FB. The connection circuit substrate FB may be positioned such that the connection circuit substrate FB corresponds to the pad area PA of the display panel DPN. Each of the connection pads FP of the connection circuit substrate FB may have at least one area which overlaps with the corresponding panel pads PP and is electrically connected thereto.

The connection circuit substrate FB may be flexible. Due to this, the connection circuit substrate FB connected to the display panel DPN may bend, such that other components such as the main circuit substrate MB connected to the connection circuit substrate FB may be arranged on the back surface of the display panel DPN.

The connection pad FP for electrically connecting to the display panel DPN may be positioned on the connection circuit substrate FB. The connection circuit substrate FB may be electrically connected to the display panel DPN by being connected to overlap the panel pad PP positioned in the pad area PA of the display panel DPN through the connection pad FP. The connection circuit substrate FB is positioned such that the connection circuit substrate FB corresponds to the pad area PA, and various electrical signals may be transmitted to the display area DA through the panel pad PP.

The main circuit substrate MB is connected to the connection circuit substrate FB, and may be connected to the other end of the connection circuit substrate FB opposite to one end of the connection circuit substrate FB connected to the display panel DPN in the connection circuit substrate FB.

The main circuit substrate MB may provide video data, control signals, power voltage, or the like to the display panel DPN. The main circuit substrate MB is a wiring substrate which is distinguished from the connection circuit substrate FB, and may include active elements and passive elements. The main circuit substrate MB may be flexible or rigid, and is not limited to any one embodiment.

A processor and/or a memory, or the like may be positioned on the main circuit substrate MB. In an example in which the display device 1 is applied to a mobile communication terminal, the processor may be an application processor including a central processing device, a graphic processing device, and/or a modem, or the like. The connection circuit substrate FB may bend, such that the main circuit substrate MB may be positioned in the back surface of the display panel DPN in a third direction DR3.

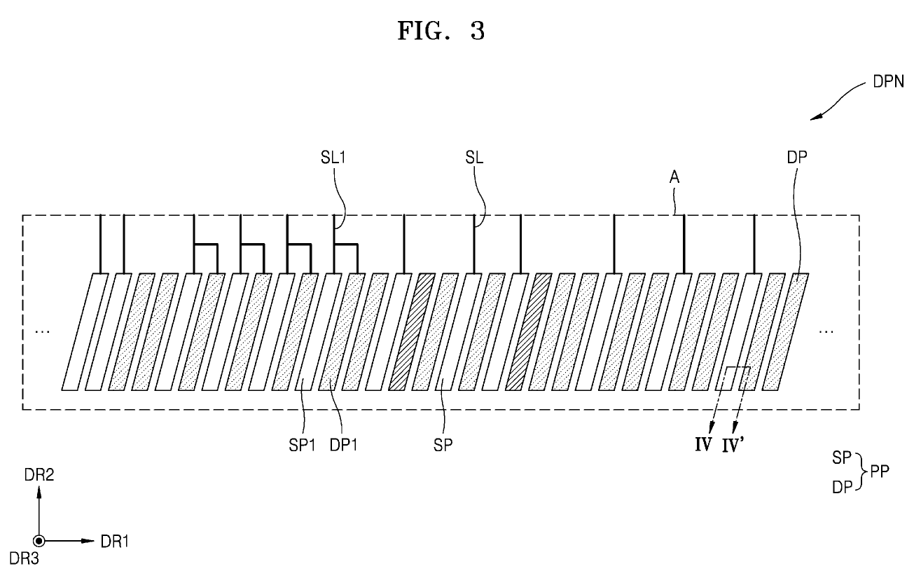

A plurality of pixels PX configured to receive signals from signal wirings (SL in FIG. 3) may be arranged on the display area DA of the display panel DPN. In some embodiments, each of the pixels PX may receive electrical signals and display corresponding lights configured to form an image. The pixels PX may be spaced apart from each other along the first direction DR1 and the second direction DR2, such that the pixels PX may be arranged in a matrix pattern. The display panel DPN may display various images by controlling the pixels PX. However, FIG. 1 is an exemplary illustration, and some configurations of the pixels PX may be arranged to overlap each other on a plane, and are not limited to any one embodiment.

Each of the pixels PX may include a display element and a driving element. The display element may include various embodiments. For example, the display element may be at least one of a liquid crystal capacitor, an organic light-emitting element, an electrophoretic element, and an electrowetting element. However, this is described as an example, and the display element may include various embodiments in which the display element may implement a video according to electrical signals, and the display element is not limited to any one embodiment.

The driving element controls the driving of each display element of each pixel PX. The driving element may include a thin film transistor. The display panel DPN according to an embodiment of the present disclosure may be driven by an active method in which each pixel PX may be independently controlled.

Although not illustrated in FIG. 1, signal lines such as scan lines, data lines, driving voltage lines, common voltage lines, and/or initialization voltage lines may be arranged on the display area DA. Each pixel PX is connected to the scan lines, the data lines, the driving voltage lines, the common voltage lines, and/or the initialization voltage lines, such that each pixel PX may receive scan signals, data voltages, driving voltages, common voltages, and/or driving voltages from these signal lines. The pixels PX may include a light-emitting element, such as a light-emitting diode. In some embodiments, touch electrodes are arranged on the display area DA of the display panel DPN, such that the touch electrodes may detect touch from a user's finger, or the like.

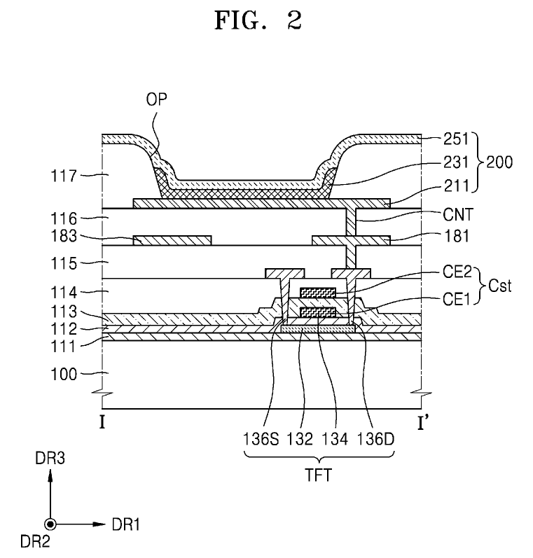

FIG. 2 is a cross-sectional view schematically illustrating an example of a part of a cross-section taken along line I-I' of FIG. 1.

Referring to FIG. 2, a buffer layer 111 may be positioned on a substrate 100 to prevent impurities from penetrating into the semiconductor layer of the thin film transistor.

The substrate 100 may include various materials such as glass, metal, or plastic, or the like. According to an embodiment, the substrate 100 may be a flexible substrate and may include a polymer resin, such as polyethersulphone (PES), polyacrylate (PAR), polyetherimide (PEI), polyethyelenennapthalate (PEN), polyethyeleneterepthalate (PET), polyphenylenesulfide (PPS), polyallylate, polyimide (PI), polycarbonate (PC), or cellulose acetate propionate (CAP).

The buffer layer 111 may include an inorganic insulating material such as silicon nitride or silicon oxide, and may be a single layer or multiple layers.

The thin film transistor TFT, a capacitor Cst, and organic light-emitting diodes 200 electrically connected to the thin film transistor TFT may be arranged on the substrate 100. The organic light-emitting diodes 200 being electrically connected to the thin film transistor TFT may be understood as a pixel electrode 211 being electrically connected to the thin film transistor TFT. The thin film transistor TFT may be a driving transistor.

The thin film transistor TFT may include a semiconductor layer 132, a gate electrode 134, a source electrode 136S, and a drain electrode 136D. The semiconductor layer 132 may include an oxide semiconductor material. The semiconductor layer 132 may include an amorphous silicon, a polycrystalline silicon, or an organic semiconductor material. The gate electrode 134 may include a single layer or multiple layers using one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) by taking into consideration adhesion to adjacent layers, surface flatness of the stacked layers, and processability, or the like.

A gate insulating layer 112 including an inorganic material such as silicon oxide, silicon nitride, and/or silicon oxynitride may be interposed between the semiconductor layer 132 and the gate electrode 134. A first interlayer insulating layer 113 and a second interlayer insulating layer 114 including an inorganic material such as silicon oxide, silicon nitride, and/or silicon oxynitride may be arranged between the gate electrode 134, the source electrode 136S and the drain electrode 136D. The source electrode 136S and the drain electrode 136D may be electrically connected to the semiconductor layer 132 through contact holes formed in the gate insulating layer 112, the first interlayer insulating layer 113, and the second interlayer insulating layer 114, respectively.

The source electrode 136S and the drain electrode 136D may include a single layer or multiple layers using one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The capacitor Cst includes a lower electrode CE1 and an upper electrode CE2 configured to overlap, with the first interlayer insulating layer 113 interposed between the lower electrode CE1 and the upper electrode CE2. The capacitor Cst may be overlapped with the thin film transistor TFT. As another embodiment, the capacitor Cst may not overlap with the thin film transistor TFT. The capacitor Cst may be covered with the second interlayer insulating layer 114.

Pixel circuits including the thin film transistor TFT and the capacitor Cst may be covered with a first insulating layer 115 and a second insulating layer 116. The first insulating layer 115 and the second insulating layer 116 may be organic insulating layers as planarizing insulating layers. The first insulating layer 115 and the second insulating layer 116 may include organic insulators such as general-purpose polymers such as polymethylmethacrylate (PMMA) or polystylene (PS), polymer derivatives having phenolic groups, acrylic polymers, imide polymers, aryl ether polymers, amide polymers, fluorine polymers, p-xylene polymers, vinyl alcohol polymers, and blends thereof. As an embodiment, the first insulating layer 115 and the second insulating layer 116 may include polyimide.

A display element, for example, an organic light-emitting diode 200, may be positioned on the second insulating layer 116. The organic light-emitting diode 200 may include a pixel electrode 211, an intermediate layer 231, and a counter electrode 251.

The pixel electrode 211 is positioned on the second insulating layer 116, and may be connected to the thin film transistor TFT through a connection electrode 181 on the first insulating layer 115. Wirings 183, such as data lines DL and driving voltage lines PL, may be arranged on the first insulating layer 115.

The pixel electrode 211 may include conductive oxide such as indium tin oxide (ITO), indium zinc oxide (IZO), zinc oxide (ZnO), indium oxide (In₂O₃), indium gallium oxide (IGO), or aluminum zinc oxide (AZO). As another embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. As a further embodiment, the pixel electrode 211 may further include a film including ITO, IZO, ZnO or In₂O₃ above or below the above-described reflective film.

A third insulating layer 117 may be positioned on the second insulating layer 116. The third insulating layer 117 covers an edge of the pixel electrode 211. The third insulating layer 117 may be a pixel definition film configured to define the pixel. For example, an opening OP may be defined in the third insulating layer 117 and expose a part of the pixel electrode 211.

The third insulating layer 117 may serve to prevent arcs, or the like from occurring at the edge of the pixel electrode 211 by increasing the distance between the edge of the pixel electrode 211 and the counter electrode 251. The third insulating layer 117 may include an organic material such as polyimide (PI) or hexamethyldisiloxane (HMDSO).

The intermediate layer 231 includes a light-emitting layer. The light-emitting layer may include a polymer, or a small-molecule organic material configured to emit lights of predetermined colors. As an embodiment, the intermediate layer 231 may include a first functional layer positioned below the light-emitting layer and/or a second functional layer positioned above the light-emitting layer. The first functional layer and/or the second functional layer may include a layer which is integrally formed across the plurality of pixel electrodes 211, or the first functional layer and/or the second functional layer may include a layer patterned to correspond to each of the plurality of pixel electrodes 211.

The first functional layer may be single layer or multiple layers. In an example in which the first functional layer includes a polymer material, the first functional layer is a hole transport layer (HTL) having a single layer structure, and may include poly-(3,4)-ethylene-dihydroxy thiophene or polyaniline. In an example in which the first functional layer includes a small-molecule material, the first functional layer may include a hole injection layer (HIL) and a hole transport layer (HTL).

In some embodiments, the second functional layer may be omitted. In some embodiments, when the first functional layer and the light-emitting layer each include a polymer material, the embodiments may include forming the second functional layer to improve the characteristics of the organic light-emitting diode. The second functional layer may be single layer or multiple layers. The second functional layer may include an electron transport layer (ETL) and/or an electron injection layer (EIL).

The counter electrode 251 is positioned to face the pixel electrode 211, with the intermediate layer 231 interposed between the counter electrode 251 and the pixel electrode 211. The counter electrode 251 may include a conductive material with a low work function. For example, the counter electrode 251 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In some embodiments, the counter electrode 251 may further include a layer such as ITO, IZO, ZnO or In₂O₃ on the (semi)transparent layer including the above-described material.

The counter electrode 251 may be positioned on the intermediate layer 231 and the third insulating layer 117. The counter electrode 251 may be formed integrally with the plurality of organic light-emitting diodes 200 in the display area DA, and may face the plurality of pixel electrodes 211.

A thin film encapsulation layer may be positioned on the counter electrode 251 as an encapsulation element. The thin film encapsulation layer serves to protect the organic light-emitting diode 200 from moisture or oxygen from the outside. The thin film encapsulation layer may have a multiple layers structure.

A functional layer such as a refractive layer, a polarizing layer, a window, or the like may be positioned on the organic light-emitting diode 200, for example, on the encapsulation element.

A problem may occur in which an electric field difference is generated between the adjacent panel pads PP arranged in the pad area PA due to differences in voltage and polarity. If the display device 1 is operated for a long time with the electric field difference occurring, the reliability of the display device 1 may deteriorate due to corrosion of the panel pads PP.

Hereinafter, the arrangement and connection relationship of signal pads SP and dummy pads DP will be examined to solve the above-described problems.

FIG. 3 is an enlarged view illustrating an example of area A in FIG. 1.

Referring to FIG. 3, the non-display area NDA may include the pad area PA where the panel pads PP are arranged along the first direction DR1. In some embodiments, the signal pads SP and the dummy pads DP may be positioned in the pad area PA. At least one of the dummy pads DP may be positioned between two adjacent signal pads SP.

All or part of the panel pads PP may be connected to a driver-IC. Driver-IC may be provided in the form of chip-on-glass, chip-on-plastic, chip-on-film, or the like and may be connected to the panel pads PP. In this case, the driver-IC and the panel pads PP may be connected using an anisotropic conductive film (ACF), or the like.

In FIG. 3, the panel pads PP are illustrated as being arranged in a single row, but is not limited thereto, and may be arranged in multiple rows.

An area between the display area DA and the pad area PA may be defined as a wiring area. A plurality of lines may be positioned in the wiring area. In this case, the plurality of wirings may include signal wirings SL extending from the signal pads SP.

The signal pads SP may be connected to the signal wirings SL, respectively. As an example, the signal pads SP may be connected to pixels PX, gate driving circuits, or the like, through the signal wirings SL, and may provide or receive driving signals, gate signals, data, or the like.

When signal pads SP are arranged without incorporating dummy pads DP as described herein, a problem may occur in which corrosion progresses quickly between the signal pads SP. Corrosion between pads may be affected by temperature, humidity, polarity differences, or electric field differences. To prevent and alleviate corrosion between the signal pads SP, a method of reducing the electric field difference between the adjacent signal pads SP, more particularly, a method of reducing the distance between the signal pads SP may be considered.

The dummy pads DP may be arranged between the signal pads SP to reduce the distance between the signal pads SP. The dummy pads DP may be pads configured not to be individually connected to the signal wirings SL, and may not transmit or receive signals. That is, the dummy pads DP may be in a floating status without being provided with separate signals. However, embodiments of the present disclosure are not limited thereto, and some dummy pads DP may be provided with predetermined voltages, and the dummy pads DP are described in more detail below.

Since the dummy pads DP do not transmit or receive signals, corrosion of the dummy pads DP themselves may not affect the reliability of the display device 1. That is, the dummy pads DP increase the distance between the signal pads SP and may be corroded in place of the signal pads SP.

However, simply arranging the dummy pads DP between signal pads SP may accelerate corrosion by forming a potential difference between the adjacent signal pads SP and dummy pads DP. To prevent this, at least one of the dummy pads DP may be electrically connected to the adjacent signal pads SP.

Descriptions herein of adjacent signal pads SP may refer to signal pads SP which follow one another in order in the first direction DR1 (or the direction opposite the first direction DR1), without a further signal pad SP in between. For example, the term “adjacent signal pads SP” may refer to a signal pad SP (e.g., first signal pad SP1) and a next signal pad SP in the first direction DR1, in which no other signal pad SP is in between. In another example, the term “adjacent signal pads SP” may refer to a signal pad SP (e.g., first signal pad SP1) and a next signal pad SP in the direction opposite the first direction DR1, in which no other signal pad SP is in between. The term “adjacent signal pads SP” may refer to a signal pad SP (e.g., first signal pad SP1) coupled to a first signal wiring SL1 and a next signal pad SP which is in the first direction DR1 (or the direction opposite the first direction DR1) and coupled to a second signal wiring SL2, where the first signal wiring SL1 and the second signal wiring SL2 are spaced apart from one another and no other signal wiring SL is in between the first signal wiring SL1 and the second signal wiring SL2.

The term “adjacent” used herein may refer to cases in which elements are relatively close to but spaced apart from one another. In some aspects, elements described as adjacent to one another may be neighboring one another but spaced apart by a predetermined distance. For example, two elements described as adjacent to one another may be neighboring one another without other elements being located between the two elements.

In a portion where there is a large difference in polarity between the adjacent signal pads SP, the signal pads SP and the adjacent dummy pads DP may not be electrically connected. However, in a portion where there is not a large difference in polarity between the adjacent signal pads SP, corrosion may be prevented by electrically connecting the adjacent signal pads SP to the dummy pads DP to eliminate the potential difference.

When the dummy pads DP are electrically connected to the adjacent signal pads SP, the distance between the signal pads SP increases, but the potential difference between the dummy pads DP and the adjacent signal pads SP disappears, such that corrosion between the dummy pads DP and the adjacent signal pads SP may be prevented and alleviated.

The signal pads SP may include a first signal pad SP1 electrically connected to a first dummy pad DP1 which is a nearest dummy pad. For example, the first dummy pad DP1 may be a dummy pad which is relatively nearest to the first signal pad SP1 from among the dummy pads DP.

The first signal pad SP1 may be connected to the first signal wiring SL1, and the first dummy pad DP1 may be connected to the first signal wiring SL1. That is, the first signal pad SP1 and the first dummy pad DP1 are respectively connected to the first signal wiring SL1, such that the first signal pad SP1 and the first dummy pad DP1 may be electrically connected to each other.

Due to this, the adjacent first signal pad SP1 and the first dummy pad DP1 electrically connected to each other have the same potential, such that corrosion between the first signal pad SP1 and the first dummy pad DP1 may be prevented or alleviated.

At least two among the signal pads SP and the dummy pads DP may be arranged such that the at least two are inclined with respect to each other rather than parallel to each other. For example, though not illustrated, the first signal pad SP1 may be inclined with respect to the first dummy pad DP1. In another example, though not illustrated, the first dummy pad DP1 may be inclined with respect to a dummy pad DP which is adjacent to the first dummy pad DP1 in the first direction. Respective upper ends of the signal pads SP and the dummy pads DP in the second direction DR2 perpendicular to the first direction DR1 may be positioned on the same line in the first direction DR1.

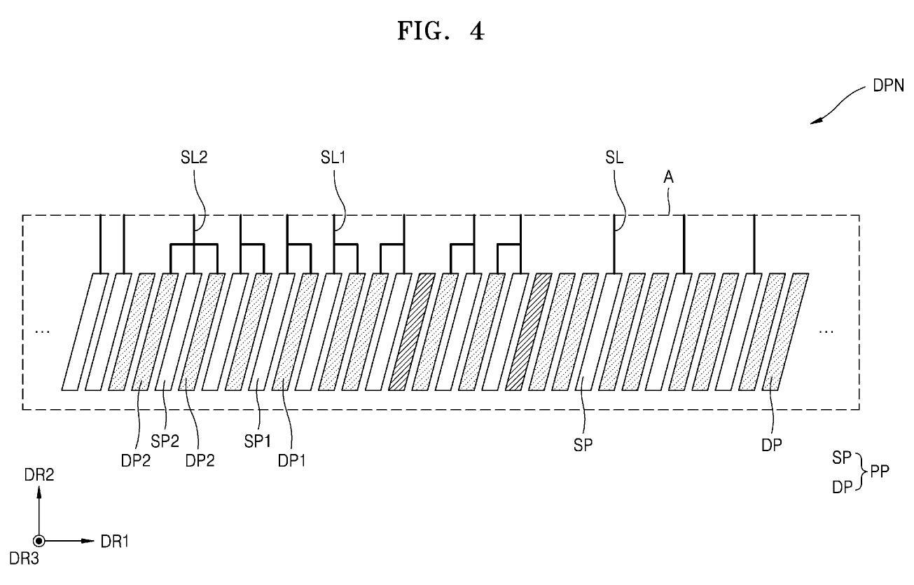

FIG. 4 is an enlarged view illustrating another example of area A in FIG. 1.

In cases where there is a large electric field difference between the signal pads SP, corrosion prevention may not be effective simply by arranging one dummy pad DP between the signal pads SP and connecting one dummy pad DP to the signal pads SP.

For a more reliable display device 1, the signal pads SP may further include a second signal pad SP2 electrically connected to second dummy pads DP2 which are respectively adjacent to opposite sides of the second signal pad SP2.

The second signal pad SP2 may be connected to the second signal wiring SL2, and the second dummy pad DP2 may be connected to the second signal wiring SL2. That is, the second signal pad SP2 and the second dummy pad DP2 are respectively connected to the second signal wiring SL2, such that the second signal pad SP2 and the second dummy pad DP2 may be electrically connected to each other.

Due to this, the adjacent second signal pad SP2 and the second dummy pad DP2 electrically connected to each other have the same potential, such that corrosion between the second signal pad SP2 and the second dummy pad DP2 may be prevented or alleviated.

In FIG. 4, the dummy pads DP located on opposite sides of the signal pad SP and closest thereto are referred to as the second dummy pads DP2, and the second dummy pads DP2 are electrically connected to the second signal pad SP2, but embodiments of the present disclosure are not limited thereto, and the second dummy pads DP2 may refer to two dummy pads DP which are arranged continuously on one side of the second signal pad SP2 and electrically connected to the second signal pad SP2.

The electric field difference between the first signal pad SP1 and another signal pad SP adjacent to the first signal pad SP1 may be smaller than the electric field difference between the second signal pad SP2 and another signal pad SP adjacent to the second signal pad SP2.

The electric field difference is proportional to the potential difference and inversely proportional to the distance between the pads. That is, the potential difference between the first signal pad SP1 and another signal pad SP adjacent to the first signal pad SP1 may be smaller than the potential difference between the second signal pad SP2 and another signal pad SP adjacent to the second signal pad SP2.

For example, with reference to FIG. 4, a single dummy pad DP is between the first signal pad SP1 and a signal pad SP which is adjacent the first signal pad SP1 in the direction opposite the first direction DR1, and two dummy pads (e.g., a dummy pad DP2, a dummy pad DP adjacent to the dummy pad DP2) are between the second signal pad SP2 and a signal pad SP which is adjacent the second signal pad SP2 in the direction opposite the first direction DR1. The distance between the first signal pad SP1 and the signal pad SP adjacent to the first signal pad SP1 in the direction opposite the first direction DR1 may be smaller than the distance between the second signal pad SP2 and a signal pad SP adjacent to the second signal pad SP2 in the direction opposite the first direction DR1. Accordingly, for example, the electric field difference (and further, the potential difference) between the first signal pad SP1 and the signal pad SP adjacent to the first signal pad SP1 in the direction opposite the first direction DR1 may be smaller than the electric field difference (and further, the potential difference) between the second signal pad SP2 and a signal pad SP adjacent to the second signal pad SP2 in the direction opposite the first direction DR1.

That is, when the electric field difference between the adjacent signal pads SP is large, the corrosion rate is faster, such that there is a great desire to protect the corresponding signal pad SP, and to this end, by arranging the second signal pad SP2 electrically connected to two second dummy pads DP2 on opposite sides, corrosion between the signal pads SP with a large electric field difference may be prevented and alleviated.

Two or more dummy pads DP may be sequentially arranged on at least one side of the second signal pad SP2. Due to this, the distance between the signal pads SP with large polarity and potential difference may be increased, and the electric field difference between the adjacent signal pads SP may be reduced. In some embodiments, the plurality of dummy pads DP between the signal pads SP may be corroded before the signal pads SP, such the plurality of dummy pads DP may serve to further protect the signal pads SP.

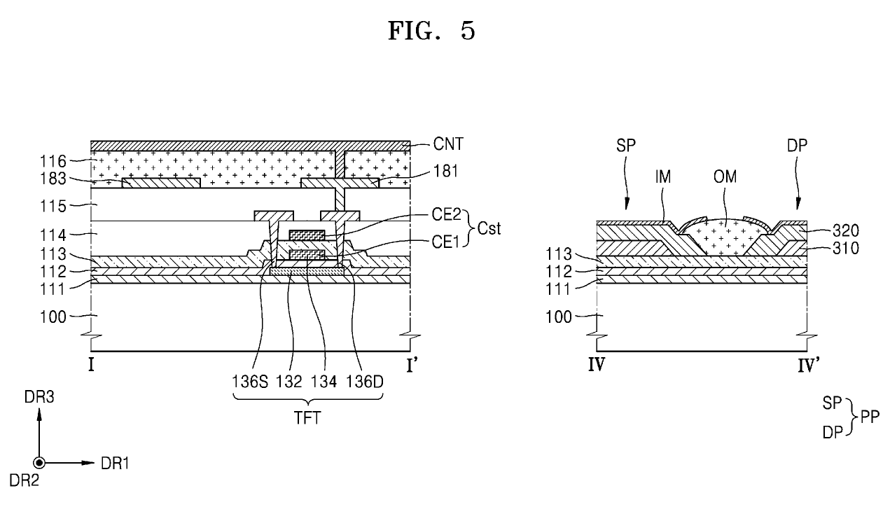

FIGS. 5 to 8 are cross-sectional views sequentially illustrating a method of manufacturing a display device according to an embodiment of the present disclosure. The example cross-sectional views are along line II-II' of FIG. 1 and line IV-IV' of FIG. 3.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” “may be stacked,” “may be arranged,” and the like include methods, processes, and techniques for disposing, forming, stacking, arranging, and positioning the element, and the like in accordance with example aspects described herein.

The display device 1 according to the present disclosure may be manufactured through preparing the substrate 100 including the display area DA and the non-display area NDA positioned outside the display area DA, and manufacturing panel pads PP along the first direction DR1 in the pad area PA of the non-display area NDA.

The preparing the substrate 100 may include sequentially stacking the substrate 100, the buffer layer 111 on the substrate 100, the gate insulating layer 112 on the buffer layer 111, and the first interlayer insulating layer 113 on the gate insulating layer 112.

The manufacturing the panel pads PP may include: arranging first pad electrodes 310 on the substrate 100, more particularly, on the first interlayer insulating layer 113, arranging second pad electrodes 320 on the first pad electrodes 310; arranging insulating materials IM and OM between the second pad electrodes 320; and removing the insulating materials IM and OM.

First, referring to FIG. 5, the first pad electrodes 310 and the second pad electrodes 320 are sequentially stacked on the substrate 100, and then the insulating materials IM and OM, more particularly, an organic insulating material OM and an inorganic insulating material IM may be sequentially stacked.

After the first pad electrodes 310 are arranged on the substrate 100, more particularly, the first interlayer insulating layer 113, the second pad electrodes 320 may be stacked on the first pad electrodes 310. The second pad electrodes 320 may cover the first pad electrodes 310. The first pad electrodes 310 and the second pad electrodes 320 which are sequentially stacked may form the panel pads PP.

The panel pads PP may include the signal pads SP or the dummy pads DP. In other words, a panel pad PP may be a signal pad SP or a dummy pad DP.

The first pad electrodes 310 may be formed at the same time as the source electrode 136S and the drain electrode 136D are formed. That is, the first pad electrodes 310 may include a single layer or multiple layers using one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), like the source electrode 136S and the drain electrode 136D.

The second pad electrodes 320 may be formed and stacked at the same time as the connection electrode 181 and the wirings 183 are formed.

The first pad electrodes 310 and the second pad electrodes 320 may each include a first layer, a second layer, and a third layer which are sequentially stacked. As an example, the first layer and the third layer may each include Ti, and the second layer may include Al.

In some embodiments, when the process of etching the pixel electrodes 211 is performed, an undercut phenomenon may occur in the Al on the side of the second layer of the second pad electrodes 320 exposed to the wet etching solution. In an example in which the undercut phenomenon occurs, moisture penetration, cracks, and corrosion into the inside of the second pad electrodes 320 may occur more easily.

To prevent the above problem, when manufacturing the display device 1 of the present disclosure, the process may further include arranging the insulating materials IM and OM between the second pad electrodes 320 and then removing the insulating materials IM and OM.

The arranging the insulating materials IM and OM between the second pad electrodes 320 may include: arranging the organic insulating material OM between the second pad electrodes 320; and arranging the inorganic insulating material IM on the second pad electrodes 320 and the organic insulating material OM.

First, the organic insulating material OM may be positioned between the second pad electrodes 320 and at the edge of the second pad electrodes 320. The organic insulating material OM may be formed at the same time as the second insulating layer 116 is formed, and may include organic insulators such as general purpose polymers such as polymethylmethacrylate (PMMA) or polystylene (PS), polymer derivatives having phenolic groups, acrylic polymers, imide polymers, aryl ether polymers, amide polymers, fluorine polymers, p-xylene polymers, vinyl alcohol polymers, and blends thereof, like the second insulating layer 116.

After the organic insulating material OM is positioned, the inorganic insulating material IM may be positioned. The inorganic insulating material IM may cover a portion of the second pad electrodes 320 and the organic insulating material OM. Since the organic insulating material OM will later be removed by a dry etching process, embodiments of the present disclosure may include positioning the inorganic insulating material IM such that the inorganic insulating material IM covers a portion of the organic insulating material OM rather than covering the entirety of the organic insulating material OM.

The inorganic insulating material IM may be formed at the same time as a contact layer CNT of the pixel electrode 211 is formed. That is, the components of the contact layer CNT and the components of the inorganic insulating material IM may be the same.

As an example, the inorganic insulating material IM may include conductive oxides such as indium tin oxide (ITO), indium zinc oxide (IZO), zinc oxide (ZnO), indium oxide (In₂O₃), indium gallium oxide (IGO), or aluminum zinc oxide (AZO), or silver (Ag), magnesium (Mg), aluminum (Al), platinum (Pt), palladium (Pd), gold (Au), nickel (Ni), neodymium (Nd), iridium (Ir), chromium (Cr), or compounds thereof. The inorganic insulating material IM may further include a film including ITO, IZO, ZnO or In₂O₃ above or below.

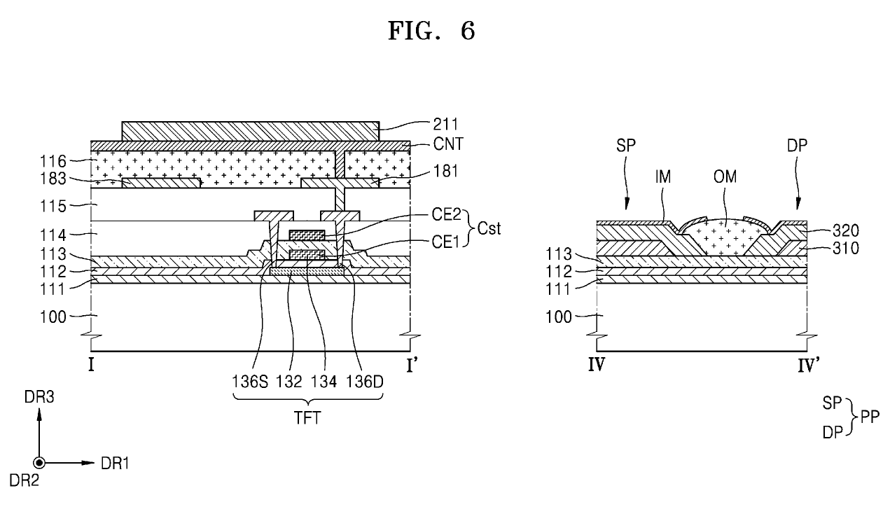

Referring to FIG. 6, a material forming the pixel electrode 211 is applied on the contact layer CNT, and the pixel electrode 211 may be formed through an etching process.

When the organic insulating material OM is not positioned between the second pad electrodes 320, the Al on the side of the second pad electrodes 320 is vulnerable to the undercut phenomenon in the process of forming the pixel electrode 211, but since the organic insulating material OM covers the edge of the second pad electrodes 320, the Al on the side of the second pad electrodes 320 may be protected from the wet etching solution that etches the pixel electrode 211.

Removing the insulating materials IM and OM may include removing the organic insulating material OM and removing the inorganic insulating material IM.

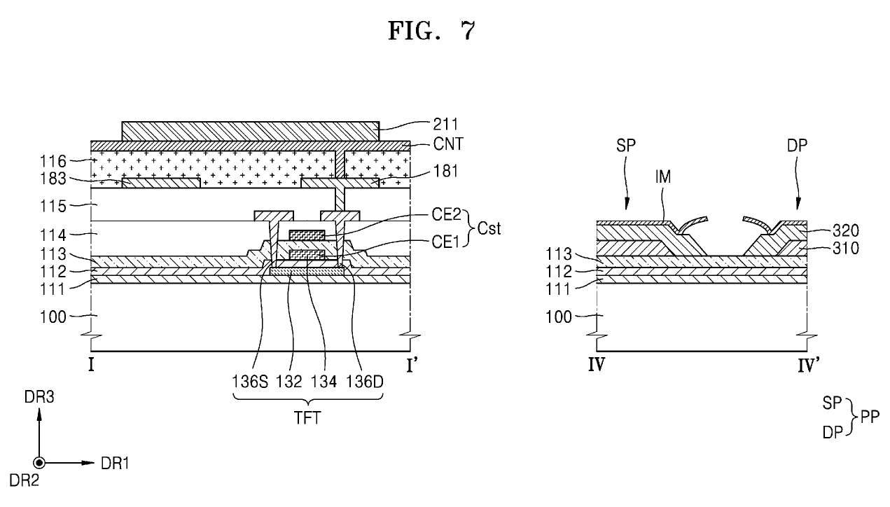

Referring to FIG. 7, the organic insulating material OM may be removed before the inorganic insulating material IM through the etching process. The inorganic insulating material IM covers only a portion of the organic insulating material OM, such that the organic insulating material OM may be removed by a dry etching process. In an example in which the organic insulating material OM is removed, the inorganic insulating material IM remains, such that the inorganic insulating material IM may protect the second pad electrodes 320.

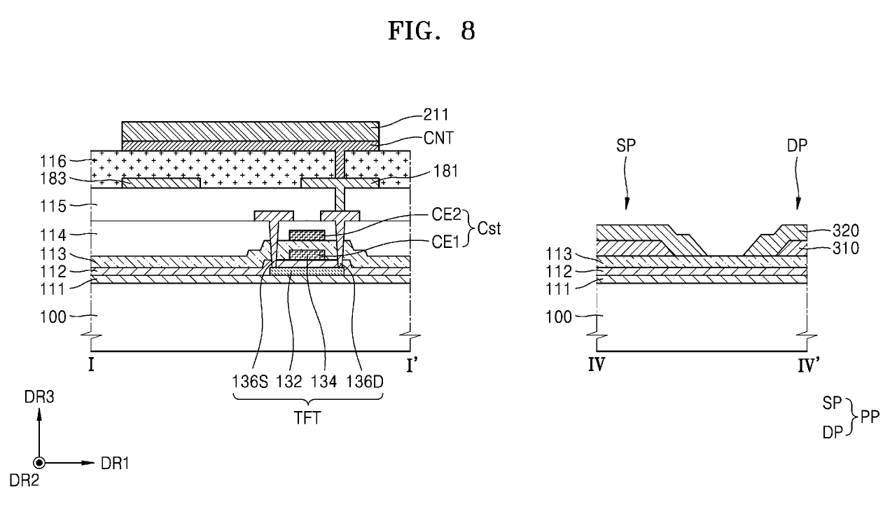

Referring to FIG. 8, the inorganic insulating material IM may be removed through an ashing process. A portion of the contact layer CNT that does not overlap with the pixel electrode 211 in the second direction DR2 may be removed together when the inorganic insulating material IM is removed.

The undercut phenomenon may be prevented or alleviated on the side of the panel pads PP manufactured through the above process, more particularly, on the edge of the second pad electrodes 320, and then, moisture penetration, cracks, and corrosion phenomena into the inside of the second pad electrodes 320 may be prevented or alleviated, and as a result, the reliability of the display device 1 may be improved.

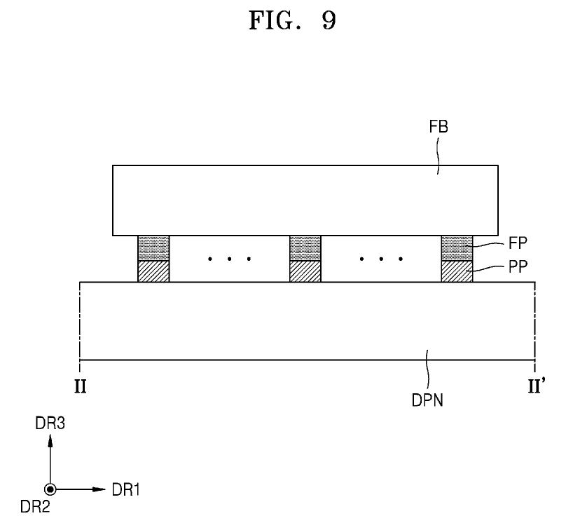

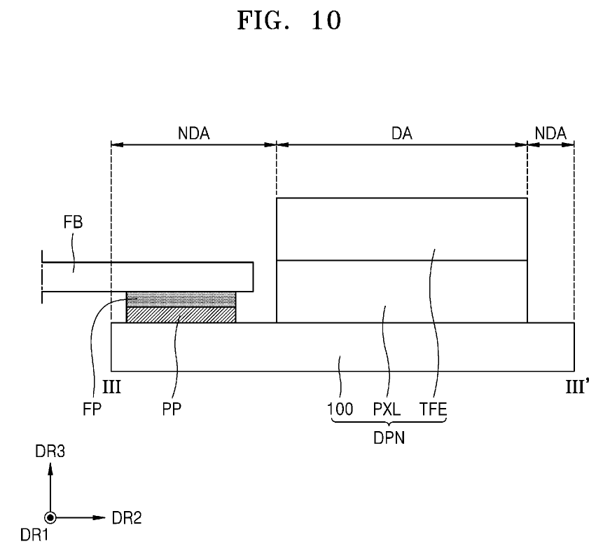

FIG. 9 is a cross-sectional view schematically illustrating a cross-section taken along line II-II' of FIGS. 1, and FIG. 10 is a cross-sectional view schematically illustrating a cross-section taken along line III-III' of FIG. 1.

Each of a plurality of signal pads SP and a plurality of dummy pads DP arranged in the non-display area NDA of the display panel DPN overlaps with the connection pads FP arranged on one side of the connection circuit substrate FB, thereby electrically connecting the connection circuit substrate FB to the display panel DPN.

As an example, referring to FIG. 9, the width of the signal pads SP and the dummy pads DP and the width of the connection pads FP are the same, and the width of the signal pads SP and the dummy pads DP and the width of the connection pads FP correspond to each other and may be connected. Although not illustrated, the width of the signal pads SP and dummy pads DP and the width of the connection pads FP may be different from each other, and the width of the signal pads SP and dummy pads DP and the width of the connection pads FP may not correspond to each other, such that the sides of the signal pads SP and dummy pads DP and the connection pads FP may not exactly match.

The signal pads SP, the dummy pads DP and the connection pads FP may be respectively formed with an appropriate width, such that the signal pads SP, the dummy pads DP and the connection pads FP may overlap and connect with each other, and such that signal pads SP, the dummy pads DP and the connection pads FP are connected and provide sufficient structural stability which supports the connection circuit substrate FB.

Referring to FIG. 10, the display panel DPN may include the display area DA positioned in the middle of the display panel DPN and the non-display area NDA on opposite sides of the display area DA.

The non-display area NDA may be electrically connected to the connection circuit substrate FB in at least one area. The connection pads FP may be connected to overlap with the panel pads PP, thereby improving the electrical connection and reliability between the connection circuit substrate FB and the display panel DPN.

The display panel DPN may include the substrate 100, the pixel layer PXL, and the encapsulation layer TFE which are stacked along the third direction DR3 in a cross-section.

The substrate 100 may be a base layer on which the pixel layer PXL is formed. The substrate 100 may be a single layer or may include plurality of insulating layers. The substrate 100 may be at least one of a glass substrate, a plastic substrate, a film, and a stacked body including a plurality of organic films and/or inorganic films, and is not limited to any one embodiment.

Although not illustrated, as described herein, the substrate 100 may include driving elements and signal lines of the pixels PX. In some embodiments, the substrate 100 may have a stacked structure of a plurality of conductive layers, a plurality of organic films and/or inorganic films.

The pixel layer PXL may be positioned on the substrate 100. The pixel layer PXL may be electrically connected to the driving elements and signal lines of the substrate 100. The pixel layer PXL includes display elements among the above-described pixels PX. In an example in which the display panel DPN is an organic light-emitting display panel, the pixel layer PXL may include an organic light-emitting layer. The display area DA may correspond to the area where the pixel layer PXL is positioned.

The encapsulation layer TFE may be positioned on the pixel layer PXL to cover the pixel layer PXL. The encapsulation layer TFE may protect the pixel layer PXL. Although not illustrated, the encapsulation layer TFE may cover the side of the pixel layer PXL. In some embodiments, according to the type of display panel DPN, the encapsulation layer TFE may be omitted or replaced with another display substrate.

The connection circuit substrate FB is positioned in the non-display area NDA of the display panel DPN to connect the main circuit substrate MB to the display panel DPN. The connection circuit substrate FB may be positioned on one side of the display panel DPN extending along a second direction DR2.

As an example, a plurality of connection circuit substrates FB may be provided and arranged along the first direction DR1. As another example, the connection circuit substrate FB may be provided as a single component, and is not limited to any one embodiment.

The display device 1 according to the embodiment may be applied to various electronic devices 10. The electronic device 10 according to an embodiment includes the above-described display device 1, and may further include a module or device having additional functions in addition to the display device 1.

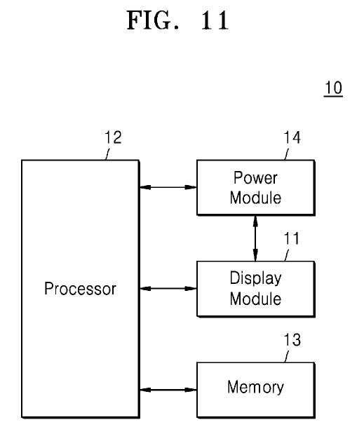

FIG. 11 is a block diagram of an electronic device according to an embodiment. Referring to FIG. 11, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information supportive of the operation of the processor 12 or the display module 11 may be stored in the memory 15. In an example in which the processor 12 executes an application stored in the memory 15, a video data signal and/or an input control signal is transmitted to the display module 11, and the display module 11 may process the received signal and output video information through a display screen.

The power module 14 may include a power supply module such as a power adapter or a battery device, or the like, and a power conversion module configured to convert power supplied by the power supply module to generate power for the operation of the electronic device 10.

At least one of the components of the above-described electronic device 10 may be included in the display device 1 according to the above-described embodiments. In some embodiments, some of the individual modules functionally included in a module may be included in the display device, while others may be provided separately from the display device. For example, the display device 1 includes a display module 11, and the processor 12, the memory 13, and the power module 14 may be provided in the form of other devices within the electronic device 10 other than the display device 1.

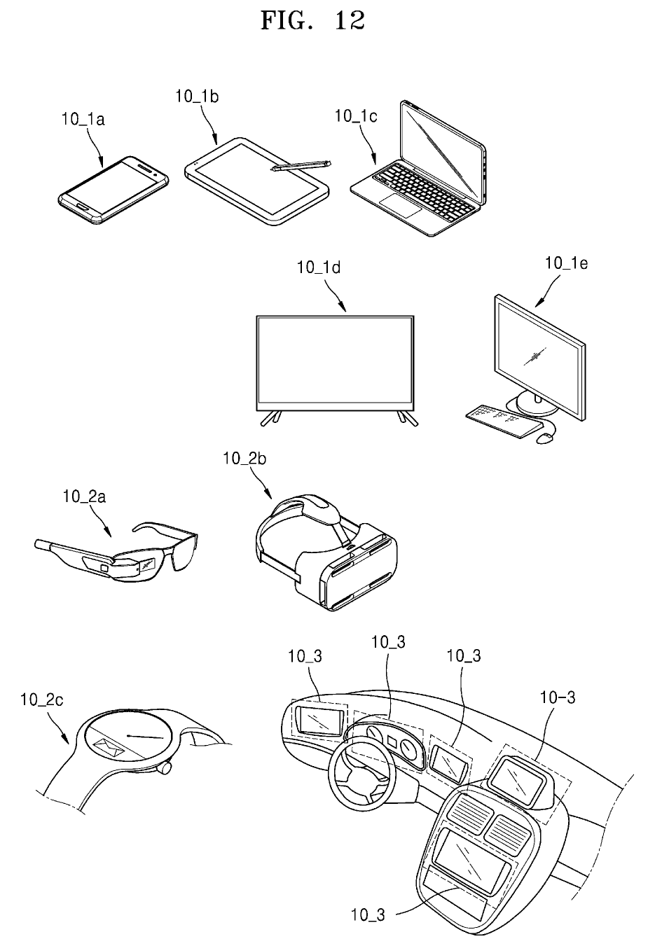

FIG. 12 is a schematic diagram of an electronic device according to various embodiments.

Referring to FIG. 12, various electronic devices to which the display device 1 according to embodiments is applied may include: image display electronic devices such as a smartphone 10_1a, a tablet PC 10_1b, a laptop 10_1c, a TV 10_1d, and a desktop monitor 10_1e; wearable electronic devices including a display module such as smart glasses 10_2a, a head mounted display 10_2b, and a smartwatch 10_2c; and vehicle electronic devices 10_3 including display modules such as a cluster, a center fascia, a center information display (CID) arranged on the dash substrate, and a room mirror display.

Each of the embodiments described herein may be implemented independently, but it is to be understood that the structure of each embodiment may be applied in combination to other embodiments.

Although the present disclosure has been described with reference to the embodiments illustrated in the drawings, these are exemplary, and it will be understood by a person skilled in the art that various changes and other equivalent embodiments are possible from the above embodiments. Therefore, the true technical scope of the present disclosure should be defined by the following claims.

The specific implementations described in the embodiments are examples, and the scope of the embodiments is not limited thereby. In some aspects, unless specifically described as "essential" or "significant," the components described are not limited to being necessary for the application of the present disclosure.

In the description of the embodiments (especially in the claims), terms such as "the" and similar terms may be in both singular and plural. In some aspects, when a range is described in an embodiment, individual values within the range are included, (unless otherwise stated), and it is the same as describing each individual value constituting the range in the detailed description. Finally, unless there is an explicit description or contradiction of the order of steps that constitute the method according to the embodiment, the steps may be performed in any suitable order. The embodiments are not necessarily limited to the order in which the steps are described. The use of all examples or exemplary terms in the embodiments is for detailed explanation, and unless limited by the claims, the scope of the embodiments is not limited by these examples or exemplary terms. In some aspects, a person skilled in the art will recognize that various modifications, combinations, and changes may be made within the scope of the claims or their equivalents, depending on design conditions and factors.

According to an embodiment of the present disclosure, a display device having improved reliability, including a dummy pad positioned between signal pads and electrically connected to the signal pads, a method for manufacturing the same, and an electronic device including the same may be implemented.

Of course, the scope of the present disclosure is not limited by these effects.

What is claimed is:

1. A display device comprising:
a substrate comprising a display area and a non-display area positioned outside the display area;
a thin film transistor positioned on the substrate; and
a light-emitting element positioned in the display area of the substrate and electrically connected to the thin film transistor,
wherein:
the non-display area comprises a pad area in which signal pads and dummy pads are arranged along a first direction,
the signal pads are connected to signal wirings, respectively, and
at least one of the dummy pads is positioned between two adjacent signal pads of the signal pads and is electrically connected to one of the two adjacent signal pads.

2. The display device of claim 1, wherein the signal pads comprise a first signal pad electrically connected to a first dummy pad which is relatively nearest to the first signal pad from among the dummy pads.

3. The display device of claim 2, wherein:
the first signal pad is connected to a first signal wiring, and
the first dummy pad is connected to the first signal wiring.

4. The display device of claim 2, wherein the signal pads comprise a second signal pad electrically connected to second dummy pads which are respectively adjacent to opposite sides of the second signal pad.

5. The display device of claim 4, wherein an electric field difference between the first signal pad and another signal pad adjacent to the first signal pad is smaller than an electric field difference between the second signal pad and another signal pad adjacent to the second signal pad.

6. The display device of claim 4, wherein two or more dummy pads are sequentially arranged on at least one side of the opposite sides of the second signal pad.

7. The display device of claim 4, wherein:
the second signal pad is connected to a second signal wiring, and
the second dummy pads are connected to the second signal wiring.

8. The display device of claim 1, wherein at least two among the signal pads and the dummy pads are arranged such that the at least two are inclined rather than parallel to each other.

9. The display device of claim 1, wherein upper ends of the signal pads and the dummy pads in a second direction perpendicular to the first direction are positioned on a same line in the first direction.

10. The display device of claim 1, further comprising:
a connection circuit substrate having a surface on which a plurality of connection pads are arranged along the first direction, wherein:
the connection circuit substrate is positioned such that the connection circuit substrate corresponds to the pad area, and
each of the plurality of connection pads has at least one area which overlaps with a corresponding signal pad and is electrically connected thereto.

11. A method of manufacturing a display device comprising:
preparing a substrate comprising a display area and a non-display area positioned outside the display area; and
manufacturing panel pads along a first direction in a pad area of the non-display area,
wherein the manufacturing the panel pads comprises:
arranging first pad electrodes on the substrate;
arranging second pad electrodes respectively on the first pad electrodes;
arranging an insulating material between the second pad electrodes; and
removing the insulating material.

12. The method of claim 11, wherein the arranging the insulating material between the second pad electrodes comprises:
arranging an organic insulating material between the second pad electrodes; and
arranging an inorganic insulating material on the second pad electrodes and the organic insulating material.

13. The method of claim 12, wherein the removing the insulating material comprises:
removing the organic insulating material; and
removing the inorganic insulating material.

14. The method of claim 11, wherein:
the panel pads comprise signal pads and dummy pads, and
at least one of the dummy pads is positioned between two adjacent signal pads of the signal pads and is electrically connected to one of the two adjacent signal pads.

15. The method of claim 14, wherein the signal pads comprise a first signal pad electrically connected to a first dummy pad which is relatively nearest to the first signal pad from among the dummy pads.

16. The method of claim 15, wherein the signal pads comprise a second signal pad electrically connected to second dummy pads which are respectively adjacent to opposite sides of the second signal pad.

17. The method of claim 16, wherein an electric field difference between the first signal pad and another signal pad adjacent to the first signal pad is smaller than an electric field difference between the second signal pad and another signal pad adjacent to the second signal pad.

18. The method of claim 17, wherein:
the first pad electrodes and the second pad electrodes each comprise a first layer, a second layer, and a third layer which are sequentially stacked,
the first layer and the third layer each comprise Ti, and
the second layer comprises Al.

19. An electronic device comprising:
a display module;
a processor;
a memory; and
a power module,
wherein:
the display module comprises:
a substrate comprising a display area and a non-display area positioned outside the display area;
a thin film transistor positioned on the substrate; and
a light-emitting element positioned in the display area of the substrate and electrically connected to the thin film transistor,
the non-display area comprises a pad area in which signal pads and dummy pads are arranged along a first direction,
the signal pads are connected to signal wirings, respectively, and
at least one of the dummy pads is positioned between two adjacent signal pads of the signal pads and is electrically connected to one of the two adjacent signal pads.

20. The electronic device of claim 19, wherein:
the signal pads comprise:
a first signal pad electrically connected to a first dummy pad which is a nearest one of the dummy pads; and
a second signal pad electrically connected to second dummy pads which are respectively adjacent to opposite sides of the second signal pad, and
an electric field difference between the first signal pad and another signal pad adjacent to the first signal pad is smaller than an electric field difference between the second signal pad and another signal pad adjacent to the second signal pad.
